(19) United States
(12) Patent Application Publication
(10) Pub. No.: US 2026/0059939 A1
(43) Pub. Date: Feb. 26, 2026

(54) LIGHT-EMITTING ELEMENT, DISPLAY DEVICE, AND METHOD FOR MANUFACTURING THE LIGHT-EMITING ELEMENT

(71) Applicant: Sharp Display Technology Corporation, Kameyama City, Mie (JP)

(72) Inventor: YOSHIHIRO UETA, Sakai City, Osaka (JP)

(21) Appl. No.: 19/102,562

(22) PCT Filed: Aug. 22, 2022
(86) PCT No.: PCT/JP2022/031518

§ 371 Date: Feb. 10, 2025

(51) Int. Cl. H10K 50/856; H10K 59/80

(52) U.S. Cl. CPC H10K 50/856; H10K 59/878

(57) ABSTRACT

Provided is a first electrode, a second electrode, an emission layer positioned between the first electrode and the second electrode, and a functional layer positioned between the first electrode and the emission layer. At least one of the first electrode and the functional layer is a light-reflective portion having a grain boundary, and whose surface adjacent to the emission layer has an average roughness of 3 to 20 nm.

### TECHNICAL FIELD

The disclosure relates to a light-emitting element, a display device, and a method for manufacturing the light-emitting element.

### BACKGROUND ART

Patent Literature 1 discloses an organic light-emitting component provided with a first electrode that is translucent, and a second electrode that is diffusely reflective, wherein the second electrode includes an electrode layer including a large number of crystals with interfaces for diffusion reflection.

### CITATION LIST

### Patent Literature

Patent Literature 1: US2017/0047552 (published on Feb. 16, 2017)

### Non-Patent Literature

Non-Patent Literature 1: “High Rate Thick Film Growth” (Ann. Rev. Mater. Sci., 7 (1997) 239.)

### SUMMARY

### Technical Field

Such known techniques unfortunately involve low efficiency of light extraction from a light-emitting element.

### Solution to Problem

A light-emitting element according to one aspect of the present disclosure is provided with the following: a first electrode; a second electrode; an emission layer positioned between the first electrode and the second electrode; and a functional layer positioned between the first electrode and the emission layer. At least one of the first electrode and the functional layer is a light-reflective portion having a grain boundary, and whose surface adjacent to the emission layer has an average roughness of 3 to 20 nm.

### Advantageous Effect of Disclosure

The aspect of the present disclosure improves the efficiency of light extraction from a light-emitting element.

### BRIEF DESCRIPTION OF DRAWINGS

FIG. 1 is a cross-sectional view of an example of the configuration of a light-emitting element according to a first embodiment.

FIG. 2 is a cross-sectional view of an example of the configuration of a reflective portion according to the first embodiment.

FIG. 3 is a cross-sectional view of an example of the configuration of the reflective portion according to the first embodiment.

FIG. 4 is a cross-sectional view of an example of the configuration of the reflective portion according to the first embodiment.

FIG. 5 is a taken image of the light-emitting element in cross-section, according to the first embodiment.

FIG. 6 is a flowchart showing an example of a method for manufacturing the light-emitting element according to the embodiments.

FIG. 7 is a diagram quoting the Thornton's zone model illustrating the structural change of a sputtered thin film.

FIG. 8 is a graph showing the current-voltage (J-V) property of the light-emitting element according to the first embodiment, and the current-voltage (J-V) property of a light-emitting element according to a comparative example.

FIG. 9 is a graph showing the current-luminance (J-L) property of the light-emitting element according to the first embodiment, and the current-luminance (J-L) property of the light-emitting element according to the comparative example.

FIG. 10 is a graph showing the current-emission efficiency (J-EQE) property of the light-emitting element according to the first embodiment, and the current-emission efficiency (J-EQE) property of the light-emitting element according to the comparative example.

FIG. 11 schematically illustrates light extraction from the light-emitting element according to the comparative example.

FIG. 12 schematically illustrates light extraction from the light-emitting element according to the first embodiment.

FIG. 13 is a cross-sectional view of an example of the configuration of a light-emitting element according to a second embodiment.

FIG. 14 is a cross-sectional view of an example of the configuration of the light-emitting element according to the second embodiment.

FIG. 15 is a cross-sectional view of an example of the configuration of the light-emitting element according to the second embodiment.

FIG. 16 is a cross-sectional view of an example of the configuration of a light-emitting element according to a third embodiment.

FIG. 17 is a plan view of an example of the configuration of a display device according to a fourth embodiment.

FIG. 18 is a cross-sectional view of an example of the configuration of a display device according to a fourth embodiment.

FIG. 19 is a cross-sectional view of an example of the configuration of the display device according to the fourth embodiment.

FIG. 20 is a cross-sectional view of an example of the configuration of a display device according to a fifth embodiment.

### DESCRIPTION OF EMBODIMENTS

### First Embodiment

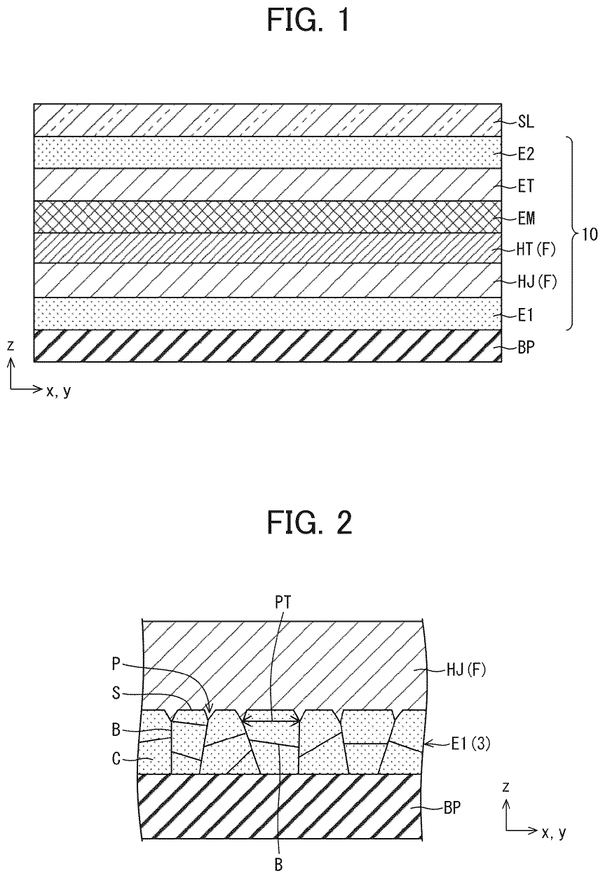

FIG. 1 is a cross-sectional view of an example of the configuration of a light-emitting element according to one embodiment of the present disclosure. As illustrated in FIG. 1, a light-emitting element 10 includes a first electrode E1, a hole injection layer HJ, a hole transport layer HT, an emission layer EM, an electron transport layer ET, and a second electrode E2 in the stated order. The light-emitting element 10 may be provided on a substrate BP and covered with a sealing film SL that prevents intrusion of water, oxygen, and other foreign substances. The first electrode E1 may be an anode, and the second electrode E2 may be a cathode. Each of the hole injection layer HJ and hole transport layer HT can be referred to as a functional layer F. The light-emitting element 10 may be a top-emission type in which the second electrode E2 is a light-transparent electrode.

The hole injection layer HJ may include a hole transport material having a higher electrical resistivity than polyethylenedioxyofen (PEDOT:PSS) doped with polystyrenesulfonic acid. The hole injection layer HJ may include a hole transport material having an electrical resistivity of 1×10⁶ Ωcm or greater. An example is a material including one or more selected from the group consisting of an oxide, a nitride, and a carbide each containing one or more of Zn, Cr, Ni, Ti, Nb, Al, Si, Mg, Ta, Hf, Zr, Y, La, Sr, and W. Among them, a desirable inorganic hole transport material is an oxide containing one or more of Zn, Cr, Ni, Ti, Nb, Al, Si, Mg, Ta, Hf, Zr, Y, La, Sr, and a more desirable inorganic hole transport material is at least one selected from NiO, MgO, MgNiO, LaNiO₃, CuO, and Cu₂O. Furthermore, a suitable hole transport material is a material in which a CN group, an SCN group, and an SeCN group are joined to metal, such as CuSCN.

The hole transport layer HT may include an organic hole transport material having a higher electrical resistivity than polyethylenedioxyofen (PEDOT:PSS) doped with polystyrenesulfonic acid. An organic hole transport material having an electrical resistivity of 1×10⁶ Ωcm or greater may be included. As the organic hole transport material, materials that are commonly used in the field can be appropriately selected; examples include materials, such as 4,4′,4″-tris(9-carbazoyl) triphenylamine (TCTA), 4,4′-bis[N-(1-naphthyl)-N-phenyl-amino]-biphenyl (NPB), zincphthalocyanine (ZnPC), di[4-(N,N-ditolylamino)phenyl] cyclohexane (TAPC), 4,4′-bis(carbazole-9-yl)biphenyl (CBP), 2,3,6,7,10,11-hexacyano-1,4,5,8,9,12-hexaazatriphenylene (HATCN), poly (N-vinylcarbazole) (PVK), poly(2,7-(9,9-di-n-octylfluorene)-(1,4-phenylene-((4-second butylphenyl)imino)-1,4-phenylene (TFB), and a poly(triphenylamine) derivative (TPD). Among them, preferred materials are a tetracyano compound, such as TFB, a carbazole derivative, such as PVK, and a triarylamine derivative, such as Poly-TPD.

FIG. 2 is a cross-sectional view of an example of the configuration of a reflective portion according to the first embodiment. As illustrated in FIG. 2, the first electrode E1 is a light-reflective portion 3 having a grain boundary B, and whose surface S adjacent to the emission layer EM has an average roughness of 3 to 20 nm. The average roughness of the surface S may measure 10 to 20 nm. Accordingly, the hole injection layer HJ is engaged in the asperities of the surface S, thus offering an anchor effect, which increases the adhesion strength between the first electrode E1 and hole injection layer HJ. Consequently, the hole injection layer HJ is less likely to detach itself from the first electrode E1.

The light-reflective portion 3 includes a plurality of crystal grains C forming the grain boundaries B. The crystal grains C may be crystals constituting a polycrystalline constituent or may be nanoparticles. The average size of the crystal grains C may be equal to or less than one-tenth of the emission peak wavelength of the emission layer EM so that Rayleigh scattering occurs. A plurality of pits P may be formed on the surface S of the light-reflective portion 3. The pits P are each a portion in which the grain boundary B is exposed to the surface S, thus producing a recess on the surface S.

The pits P preferably enhance the adhesion strength between the first electrode E1 and hole injection layer HJ without deteriorating the electrical property and emission property of the light-emitting element 10. The pits P preferably have an average depth of 3.0 to 50 nm. The pits P with less than 3.0 nm depth on average reduces the anchor effect. The pits P with more than 50 nm depth on average may possibly deteriorate the electrical connection between the first electrode E1 and hole injection layer HJ.

The average pit-to-pit distance between the plurality of pits P (an average of distances PT between adjacent pits) may measure 3 to 50 nm. The average pit-to-pit distance may be equal to or greater than the average size of the crystal grains. The average pit-to-pit distance that is less than 3 nm, or less than the average size of the crystal grains C may possibly deteriorate the electrical connection between the first electrode E1 and hole injection layer HJ. The average pit-to-pit distance that is more than 50 nm, or more than the average size of the crystal grains C reduces the anchor effect.

The first electrode E1 and the hole injection layer HJ are not mutually soluble, and hence, the adhesion strength between them depends on resistance adhesion brought about by the anchor effect. The pits P increase the area of the surface S and increase the anchor effect. The configuration according to the present disclosure offers an effect in which an improvement of the adhesion strength avoids detachment, thus improving the manufacturing yield of the light-emitting element 10. In the known techniques, the resistance adhesion is weaker than welding, thereby possibly causing the hole injection layer HJ to detach itself from the first electrode E1. Such inter-layer detachment leads to an element break, thus reducing the manufacturing yield.

On the other hand, the surface S whose asperity roughness is excessively large deteriorates quantum-dots arrangement in the emission layer EM, which is disposed over the first electrode E1 (light-reflective portion 3). The deterioration of the quantum-dots arrangement causes a reduction in carrier injection into the quantum dots, thereby deteriorating the electrical property and emission property of the light-emitting element 10. The area and average roughness of the surface S are in substantially inverse proportion to the average pit-to-pit distance under the condition where the pits P have a certain average depth. At an average pit-to-pit distance of 5 nm or greater, the surface S preferably has an average roughness of 20 nm or less. At an average pit-to-pit distance of 20 nm or less, the surface S preferably has an average roughness of 5 nm or greater. The product of the average pit-to-pit distance and average roughness preferably ranges from 30 to 150 nm².

The average pit-to-pit distance may be in correlation to the average roughness of the surface S and the average depth of the pits P. For instance, the average pit-to-pit distance may be equal to or less than either the average roughness of the surface S or the average depth of the pits P, whichever is larger. For instance, the average pit-to-pit distance may be equal to or less than the geometric mean of the average roughness of the surface S and the average depth of the pits P.

The grain boundary B may be a crystalline mismatching surface in which at least one of the crystal lattice and crystal orientation of the crystal grains C is different. In this case, light scatters at the grain boundary B. The grain boundary B may be an internal fracture surface of the first electrode E1 (light-reflective portion 3). In this case, light scatters at the grain boundary B.

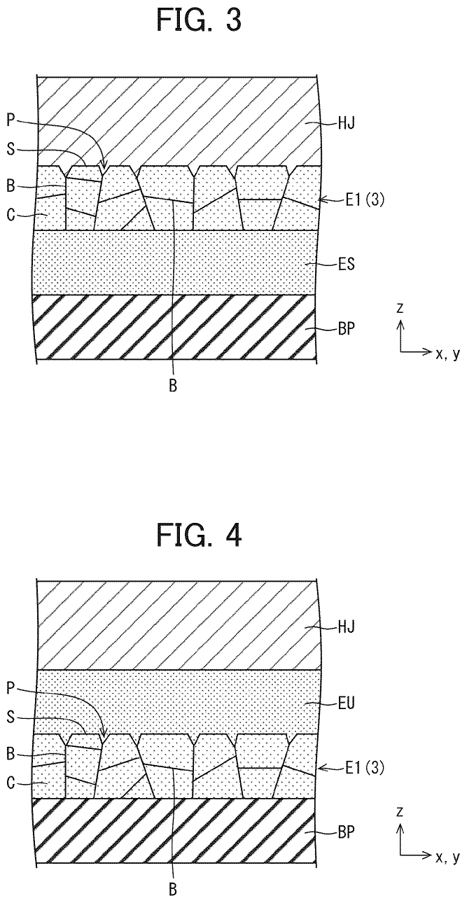

FIGS. 3 and 4 are cross-sectional views of examples of the configuration of the reflective portion according to the first embodiment. In some cases, the first electrode E1 is accompanied by a conductive layer ES disposed thereunder, as illustrated in FIG. 3. For example, when the first electrode E1 is formed from a light-transparent metal film containing, but not limited to, indium zinc oxide (InZnO) or indium gallium zinc oxide (InGaZnO), the conductive layer ES having a higher light reflectivity than the first electrode E1 may be positioned under the first electrode E1. The conductive layer ES may have a smaller work function than the first electrode E1; for instance, it may be formed from a light-reflective metal film containing aluminum (Al) or silver (Ag). In some cases, the first electrode E1 is accompanied by a conductive layer EU disposed thereover, as illustrated in FIG. 4. For example, when the first electrode E1 is formed from a light-reflective metal film containing Al or Ag, the conductive layer EU having a larger work function than the first electrode E1 may be positioned over the first electrode E1. The conductive layer EU may have high light transparency; for instance, it may be formed from a light-transparent metal film containing, but not limited to, InZnO or InGaZnO.

The average roughness of the surface S, the average depth of the pits P, and the average size of the crystal grains C can be obtained from a photomicrograph of the cross-section of the first electrode E1 (light-reflective portion 3). For easy description, this section will describe, by way of example, the first electrode E1 imaged with a transmission electron microscope (TEM).

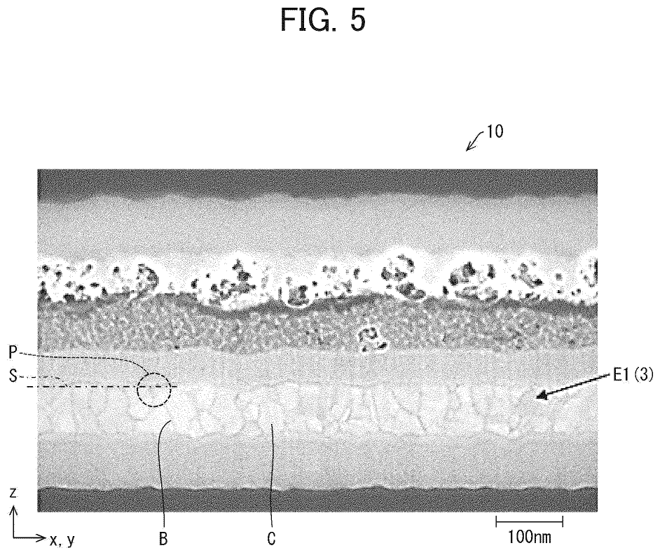

FIG. 5 is a cross-sectional view of the imaged light-emitting element according to this embodiment. As shown in FIG. 5, the grain boundaries B and crystal grains C of the first electrode E1 can be seen. Here, the photomicrograph is an image taken within a width equal to or greater than 500 nm in an in-plane direction (X- or Y-direction) orthogonal to the layer thickness direction. First, a plurality of measurement points are determined on the surface S of the first electrode E1, and the position of each measurement point in the layer thickness direction (Z-direction) is measured. A minimum of 20 measurement points per 100 nm width is acceptable. The measurement points are specified at regular intervals. In imaging within a width equal to or greater than 500 nm, 100 or more measurement points are specified within the imaging range, and the individual measurement points are specified at regular intervals. Moreover, the average position of all the measurement points in the layer thickness direction is calculated, and the arithmetic average of the difference (absolute value) between the average position and the position in the layer thickness direction of all the measurement points is determined as the average roughness of the surface S.

Subsequently, the grain boundary B is extracted from the photomicrograph. The extraction may be performed through human visual recognition, through image processing by AI or a computer, or through their combination. For example, a human designates the range of the first electrode E1 in the photomicrograph, and a computer extracts a position with a high contrast ratio between adjacent pixels from the designated range. Then, with each region sectioned by the grain boundaries B being defined as the cross-section of a corresponding one of the crystal grains C, the distances between the grain boundaries B facing each other in two or more directions may be measured for each crystal grain C, and the arithmetic average of these distances may be defined as the size of the crystal grain C. The cross-sectional area of each crystal grain C may be measured, and the diameter of a circle having the same area as the cross-sectional area may be defined as the size of the crystal grain C. The arithmetic average of the sizes of the plurality of crystal grains C is defined as the average size of the crystal grains C. The distance between the grain boundaries B facing each other in the layer thickness direction (Z-direction) may be measured for each crystal grain C, and the arithmetic average of these distances may be defined as the average thickness of the crystal grains C. The distance between the grain boundaries B facing each other in the in-plane direction (X-, or Y-direction) may be measured for each crystal grain C, and the arithmetic average of these distances may be defined as the average width of the crystal grains C. Not less than 100 crystal grains C are measured per 5000 nm² in cross-sectional area. Hereinafter, the particle diameter, thickness, and width of the crystal grains C will be referred to as the size of the crystal grains C comprehensively. The average size of the crystal grains C may be any one of the average particle diameter, average thickness, and average width of the crystal grains C.

Subsequently, the pits P are extracted from the photomicrograph. The extraction may be performed through human visual recognition, through image processing by AI or a computer, or through their combination. For example, firstly, a site with an intersection at which the surface S and the grain boundary B intersect is defined as a pit P. Alternatively, for example, a site at which the grain boundary B is observed on the surface S within a range lower than the average position of the surface S in the layer thickness direction may be defined as a pit P. Then, the distance from the lowest position in each pit P in the layer thickness direction (Z-direction) to the average position of the surface S in the layer thickness direction is measured, and the arithmetic average of these distances is defined as the average depth of the pits P. Moreover, the distances in the in-plane direction (X-, or Y-direction) between the lowest positions in mutually adjacent pits P in the layer thickness direction is measured, and the average of these distances is defined as the average pit-to-pit distance. It is noted that of the sites defined as the pits P, sites at which the upper layer (e.g., hole injection layer HJ) is engaged in the pits P, and at which the material of the upper layer is observed within the pits P may be regarded as effective pits P. Moreover, the average depth and average pit-to-pit distance of these effective pits P may be calculated. Here, the pits P to be measured are at 30 or more sites per 500 nm width.

### Manufacturing Method

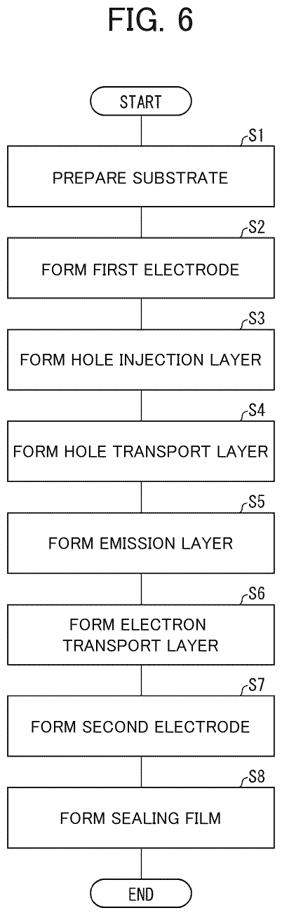

FIG. 6 is a flowchart showing an example of a method for manufacturing the light-emitting element according to this embodiment. As shown in FIG. 6, Step S1 is preparing the substrate BP, followed by Step S2 of forming the first electrode E1 (light-reflective portion) onto the substrate BP. The next is Step S3 of forming the hole injection layer HJ onto the first electrode E1, followed by Step S4 of forming the hole transport layer HT onto the hole injection layer HJ, followed by Step S5 of forming the emission layer EM onto the hole transport layer HT, followed by Step S6 of forming the electron transport layer ETL onto the emission layer EM, followed by Step S7 of forming the second electrode E2 onto the electron transport layer ETL. The next is Step S8 of forming the sealing film SL so as to cover the light-emitting element 10. The hole injection layer HJ and the hole transport layer HT can be formed by the use of a hole transport material.

In Step S2, the first electrode E1 is formed as the light-reflective portion 3 having the grain boundary B, and whose surface S adjacent to the emission layer EM has an average roughness of 3 to 20 nm. Various methods for forming polycrystals can be applied in forming the first electrode E1.

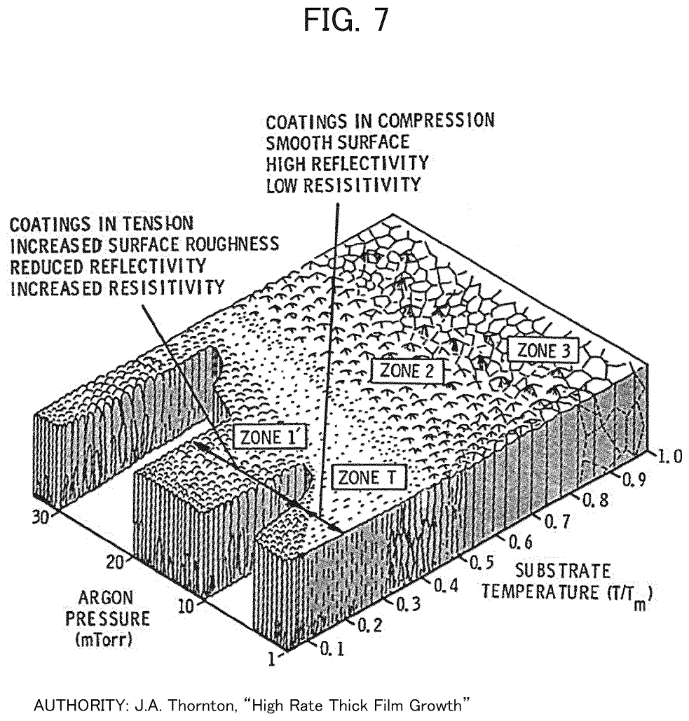

FIG. 7 is a diagram quoting the Thornton's zone model illustrating the structural change of a sputtered thin film, and quoted from J. A. Thornton, “High Rate Thick Film Growth” (Ann. Rev. Mater. Sci., 7 (1997) 239.). As shown in FIG. 7, under the condition that the pressure of argon gas in Zone 3 is small, there are grain boundaries in the sputtered thin film, and the surface of the sputtered thin film is relatively flat and has fine pits.

For example, the first electrode E1 can be formed under the condition that the pressure of argon gas in Zone 3 is small through sputtering. To be specific, the first electrode E1 can be formed under the conditions that the temperature (T) of the substrate BP is, at an absolute temperature, equal to or greater than 80% of the melting point (Tm) of the first electrode E1, and that the pressure of argon gas is equal to or less than 20 mTorr. Here, Torr is a unit indicating pressure, and 1 Torr is equal to 133.32 Pa. Suitable materials (electrode materials) for the first electrode E1 include aluminum (Al), silver (Ag), and their alloys.

The first electrode E1 may be formed through sputtering under the conditions that a glass substrate is used as the substrate BP, that the temperature of the substrate BP is raised to a high temperature of about 200 degrees Celsius (i.e., 473 K), that argon gas is introduced into a chamber, and that the pressure of the argon gas within the chamber is lowered to about 1 Pa or less. As a result, the average size of the crystal grains C in the first electrode E1 ranges from 3 to 50 nm, and at the same time, the pits P with an average depth of 3 to 50 nm are formed in the surface S of the first electrode E1. Here, the product of a ratio V_{Ar}/V and the chamber's inside pressure measured by a pressure gauge constitutes the pressure of the argon gas, where V_{Ar} denotes the amount of argon gas supply, and where V denotes the total amount of supply of gases other than the argon gas. In some cases, gases, such as nitrogen and oxygen, are supplied other than the argon gas. For instance, the average size of the crystal grains C may be any one of a range of 3 to 15 nm, a range of 3 to 20 nm, a range of 3 to 30 nm, a range of 3 to 40 nm, a range of 3 to 50 nm, a range of 10 to 15 nm, a range of 10 to 20 nm, a range of 10 to 30 nm, a range of 10 to 40 nm, and a range of 10 to 50 nm. Here, the pits P are formed at the intersections where the surface S intersects the grain boundaries B. The average size of the pits C may be less than the average size of the crystal grains C. For instance, the average depth of the pits C may be a range of 3 to 15 nm, a range of 3 to 20 nm, a range of 3 to 30 nm, a range of 3 to 40 nm, a range of 3 to 50 nm, a range of 10 to 15 nm, a range of 10 to 20 nm, a range of 10 to 30 nm, a range of 10 to 40 nm, and a range of 10 to 50 nm. In accordance with the Thornton's zone model, the size of the crystal grains C and the depth of the pits P can be controlled; setting the pressure of the argon gas on the order of 10 to 100 Pa can make the average size of the crystal grains C smaller. Further, fixing the pressure and lowering the temperature of the substrate BP can form the crystal grain C having a columnar shape (and a shape close to a columnar shape) extending in the layer thickness direction of the first electrode E1. Here, the wording “the order of 10 to 100 Pa” means a pressure in the unit of 10 Pa or 100 Pa and is a pressure of 10 Pa inclusive to 1000 Pa exclusive.

For example, the first electrode E1 can be formed by sintering powders, or combining a heat treatment with printing by the use of ink containing nanoparticles. Instead of or in addition to the foregoing, the first electrode E1 can be formed through various methods of producing an internal fracture. For example, the first electrode E1 undergoes a rapid temperature change to generate an internal stress, thereby producing an internal fracture in the first electrode E1. The average size of the crystal grains C can be affected by mechanical properties, such as the material's elasticity and material's brittleness of the first electrode E1. The harder the material of the first electrode E1 is, the more easily the first electrode E1 is broken, and the smaller the crystal grains C are.

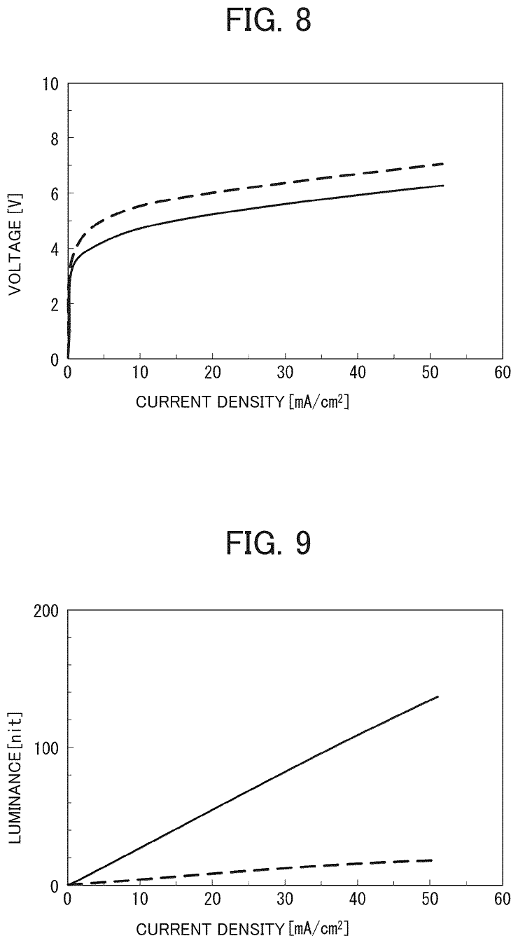

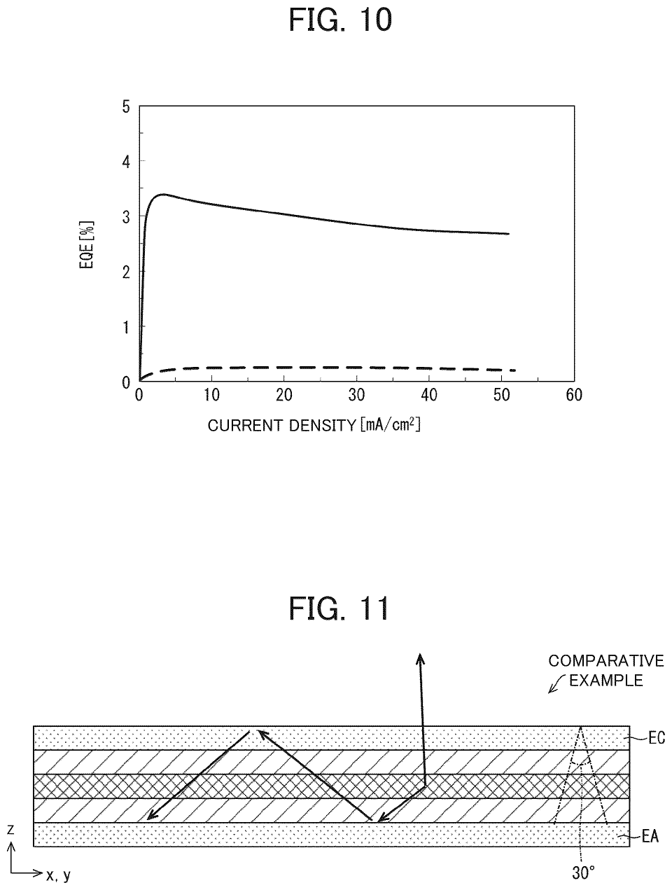

FIG. 8 is a graph showing the current-voltage (J-V) property of the light-emitting element according to the first embodiment, and the current-voltage (J-V) property of a light-emitting element according to a comparative example. FIG. 9 is a graph showing the current-luminance (J-L) property of the light-emitting element according to the first embodiment, and the current-luminance (J-L) property of the light-emitting element according to the comparative example. FIG. 10 is a graph showing the current-emission efficiency (J-EQE) property of the light-emitting element according to the first embodiment, and the current-emission efficiency (J-EQE) property of the light-emitting element according to the comparative example. In each drawing, the measurements according to the first embodiment are denoted by solid lines, and the measurements according to the comparative example are denoted by broken lines.

The first electrode E1 according to the first embodiment was formed through sputtering under the condition that the gas pressure in Zone 3 (see FIG. 7) is small. On the other hand, a first electrode EA according to the comparative example was formed through vacuum evaporation. The materials and thicknesses of the other layers were the same between the first embodiment and the comparative example.

FIG. 8 reveals that voltage with respect to current is smaller in the first embodiment than that in the comparative example. Thus, based on the fact that the first electrode E1 is the light-reflective portion 3, the electrical resistance of the light-emitting element 10 according to the first embodiment is reduced. This is presumably because the electrical connection improves thanks to improvement in the mechanical adhesion between the first electrode E1 and hole injection layer HJ, thereby improving hole injection efficiency. In addition or alternatively, it is presumed that the hole injection efficiency is improved by electric-field concentration in the pits P.

FIG. 9 reveals that luminance with respect to current is larger in the first embodiment than that in the comparative example. Furthermore, FIG. 10 reveals that external quantum efficiency is larger in the first embodiment than that in the comparative example. This is presumably because the grain boundary B of the first electrode E1 (light-reflective portion 3) scatters and reflects light, thus improving the efficiency of light extraction from the light-emitting element 10.

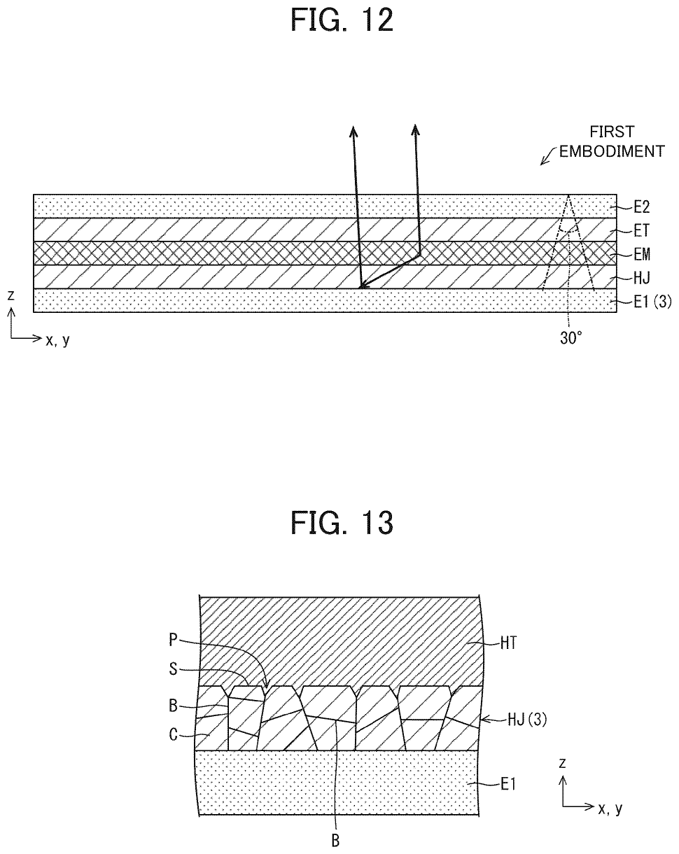

FIG. 11 illustrates light extraction from the light-emitting element according to the comparative example. FIG. 12 illustrates light extraction from the light-emitting element according to the first embodiment. It is noted that for easy description, the following will describe a configuration in which an upper electrode is in contact with the atmosphere. As illustrated in FIG. 11, in the light-emitting element according to the comparative example, light emitted from its emission layer obliquely (at a large angle with respect to the normal) and reflected by a lower electrode EA enters an upper electrode EC at a large incident angle and is totally reflected. At a typical critical angle of 15°, only light entering a cone with a tip angle of 30° can be extracted from the light-emitting element, and 25% light extraction efficiency is a theoretical limit.

On the other hand, as illustrated in FIG. 12, in the light-emitting element 10 according to the first embodiment, light emitted from the emission layer EM obliquely (at a large angle with respect to the normal) easily enters the second electrode E2 at a smaller incident angle than the comparative example due to the optical property (at least one of light scatter property and irregular reflection property) of the first electrode E1 (light-reflective portion 3), and the light highly probably goes out. Consequently, the first embodiment offers higher light extraction efficiency than the comparative example.

To improve light extraction efficiency, the light-reflective portion 3 preferably scatters light through Rayleigh scattering. In Mie scattering, incident light strongly scatters in its traveling direction, whereas in Rayleigh scattering, incident light scatters isotropically. The condition for Rayleigh scattering is that the size of the crystal grain C is equal to or less than one-tenth of the wavelength of incident light. Hence, the average size of the crystal grains C is preferably equal to or less than one-tenth of the emission peak wavelength of the emission layer EM. The average size of the crystal grains C may be their average particle diameter, average thickness, or average width.

### Second Embodiment

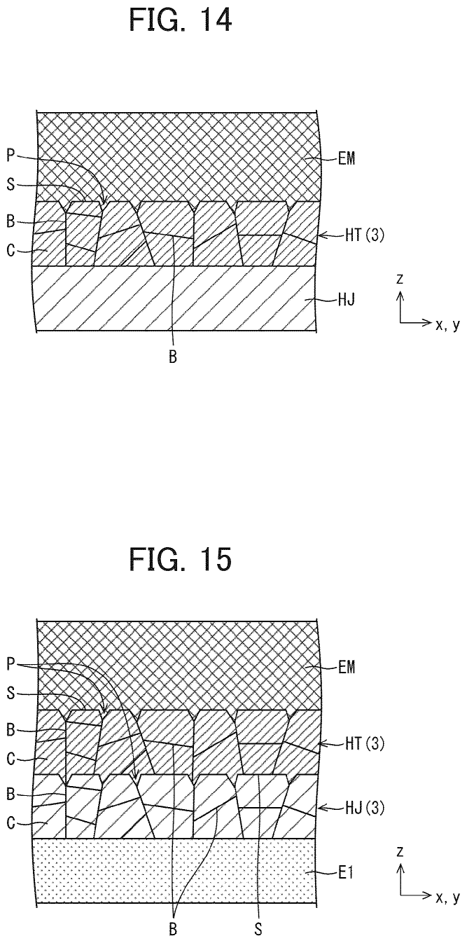

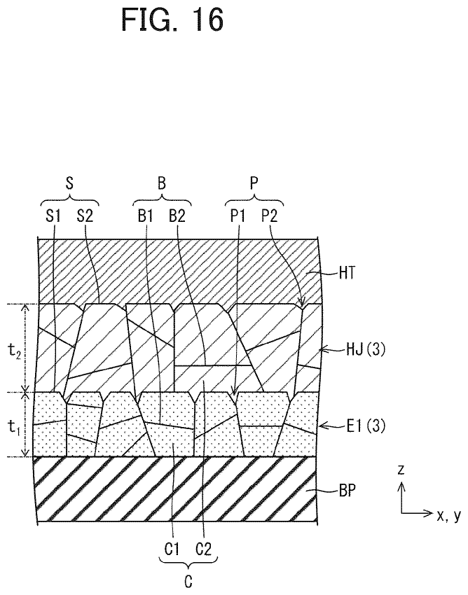

FIGS. 13 to 15 are cross-sectional views of examples of the configuration of a light-emitting element according to a second embodiment. As illustrated in FIG. 13, the hole injection layer HJ (functional layer F) may be the light-reflective portion 3 having the grain boundary B, and whose surface S adjacent to the emission layer EM has an average roughness of 3 to 20 nm. As illustrated in FIG. 14, the hole transport layer HT (functional layer F) may be the light-reflective portion 3 having the grain boundary B, and whose surface S adjacent to the emission layer EM has an average roughness of 3 to 20 nm. As illustrated in FIG. 15, each of the hole injection layer HJ (functional layer F) and hole transport layer HT (functional layer F) may be the light-reflective portion 3 having the grain boundary B, and whose surface S adjacent to the emission layer EM has an average roughness of 3 to 20 nm. The light-reflective portion 3 formed of, for instance, an organic hole transport material may have the grain boundary B constituting an internal fracture surface of the organic layer.

The second embodiment, in which the light-reflective portion 3 is positioned between the first electrode E1 and the emission layer EN, offers an effect similar to that in the first embodiment. At least one of the hole injection layer HJ (light-reflective portion 3) and hole transport layer HT (light-reflective portion 3) may be a layer (coated layer) containing metal oxide nanoparticles.

### Third Embodiment

FIG. 16 is a cross-sectional view of an example of the configuration of a light-emitting element according to a third embodiment. As illustrated in FIG. 16, each of the first electrode E1 and hole injection layer HJ (functional layer) is the light-reflective portion 3. The first electrode E1 includes a plurality of crystal grains C1 forming grain boundaries B1, and on a surface S1 of the first electrode E1 adjacent to the emission layer EM is a plurality of pits P1. The hole injection layer HJ includes a plurality of crystal grains C2 forming grain boundaries B2, and on a surface S2 of the hole injection layer HJ adjacent to the emission layer EM is a plurality of pits P2.

The average size of the crystal grains C1 and C2 across the first electrode E1 and hole injection layer HJ is the average size of the crystal grains C1 and C2 subjected to weighted average by the thicknesses of the first electrode E1 and hole injection layer HJ. Let the thickness of the first electrode E1 be denoted as t₁, let the average size of the crystal grains C1 within the first electrode E1 be denoted as N₁, let the thickness of the hole injection layer HJ be denoted as t₂, and let the average size of the crystal grains C2 within the hole injection layer HJ be denoted as N₂. Accordingly, the average size of the crystal grains C (C1 and C2) across the first electrode E1 and hole injection layer HJ is (t₁N₁+t₂N₂)/(t₁+t₂). The average size of the crystal grains C (C1 and C2) across the first electrode E1 and hole injection layer HJ is preferably equal to or less than one-tenth of the emission peak wavelength of the emission layer EM. The average size may be their average particle diameter, average thickness, or average width.

In the first electrode E1, the average depth of the pits P1 on the surface S1, which is adjacent to the emission layer EM, may range from 3 to 50 nm. In the hole injection layer HJ, the average depth of the pits P2 on the surface S2, which is adjacent to the emission layer EM, may range from 3 to 50 nm. In the first electrode E1, the average pit-to-pit distance between the plurality of pits P1 may be equal to or greater than the average size of the plurality of crystal grains C1. In the hole injection layer HJ, the average pit-to-pit distance between the plurality of pits P2 may be equal to or greater than the average size of the plurality of crystal grains C2.

The average pit-to-pit distance between the plurality of pits P1 preferably ranges from 3 to 50 nm. The average pit-to-pit distance between the plurality of pits P1 may be in correlation to the average roughness of the surface S1 and the average depth of the plurality of pits P1. For instance, the average pit-to-pit distance between the plurality of pits P1 may be equal to or less than either the average roughness of the surface S1 or the average depth of the plurality of pits P1, whichever is larger. The average pit-to-pit distance between the plurality of pits P1 may be equal to or less than the geometric mean of the average roughness of the surface S1 and the average depth of the plurality of pits P1.

Likewise, the average pit-to-pit distance between the plurality of pits P2 may range from 3 to 50 nm. The average pit-to-pit distance between the plurality of pits P2 may be in correlation to the average roughness of the surface S2 and the average depth of the plurality of pits P2. For instance, the average pit-to-pit distance between the plurality of pits P2 may be equal to or less than either the average roughness of the surface S2 or the average depth of the plurality of pits P2, whichever is larger. The average pit-to-pit distance between the plurality of pits P2 may be equal to or less than the geometric mean of the average roughness of the surface S2 and the average depth of the plurality of pits P2.

### Fourth Embodiment

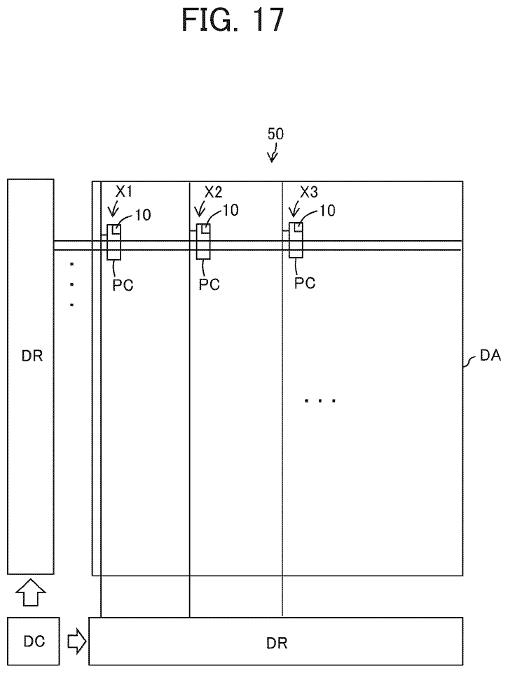

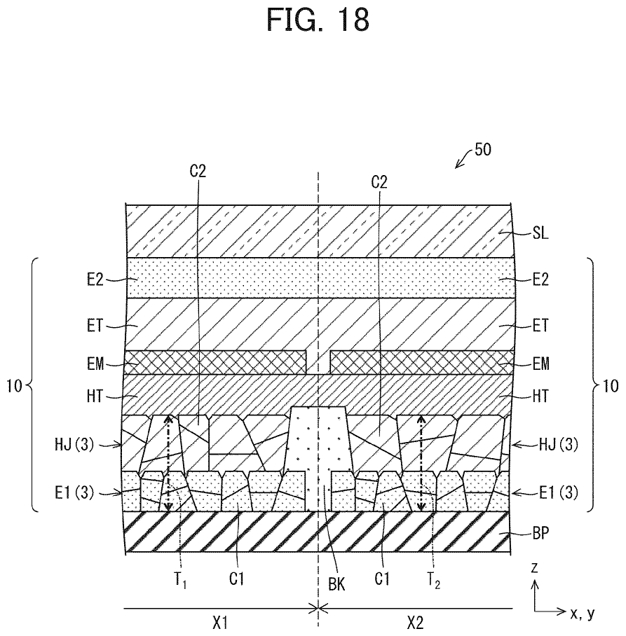

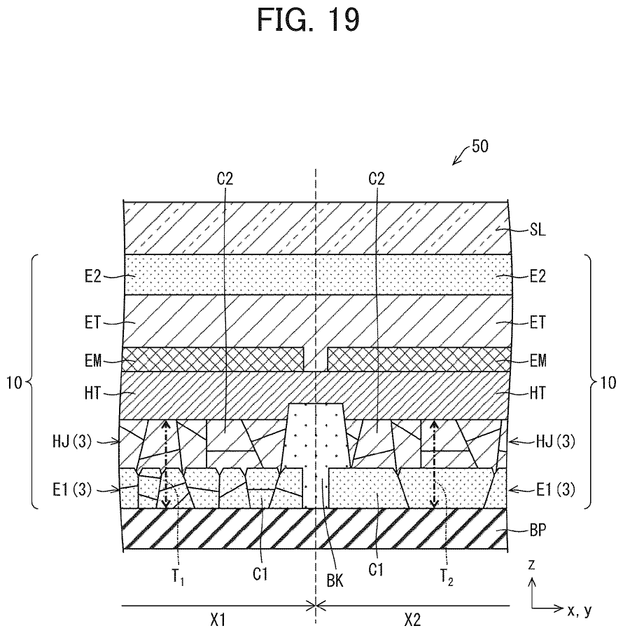

FIG. 17 is a plan view of an example of the configuration of a display device according to a fourth embodiment. FIGS. 18 and 19 are cross-sectional views of examples of the configuration of the display device according to the fourth embodiment. As illustrated in FIG. 17, the display device, 50, according to the fourth embodiment includes a display unit DA, a driver circuit DR that drives the display unit DA, and a control unit DC that controls the driver circuit DR. The display unit DA includes a first subpixel X1, a second subpixel X2, and a third subpixel X3 that emit mutually different colors of light (that is, these subpixels have mutually different emission peak wavelengths). Each the first subpixel X1, second subpixel X2, and third subpixel X3 includes the light-emitting element 10, and a pixel circuit PC connected to the light-emitting element 10.

As illustrated in FIG. 18, the display device 50 may include an edge cover BK covering the edge of the first electrode E1, and a sealing film SL covering the light-emitting element 10. The light-emitting element 10 included in each of the first subpixel X1 and second subpixel X2 includes the first electrode E1 being the light-reflective portion 3, and the hole injection layer HJ being the light-reflective portion 3. It is preferable that the light-emitting elements 10 in the respective first subpixel X1 and second subpixel X2 exhibit substantially equal external quantum efficiency regardless of the color of light emitted from the light-emitting elements 10. In other words, it is preferable that their theoretical limits of light extraction efficiency be substantially equal. Equal EQE enables the first subpixel X1 and second subpixel X2 to be driven and controlled similarly. Simplified drive and control can reduce the costs for the substrate BP and a control algorithm.

The light extraction efficiency depends on the layer thickness T₁ (the total thickness of the first electrode E1 and hole injection layer HJ in the first subpixel X1), the layer thickness T₂ (the total thickness of the first electrode E1 and hole injection layer HJ in the second subpixel X2), and the intensity, I, of Rayleigh scattering in each subpixel. The intensity I is expressed by the following equation.

$$I = 4.5 \times {I}_{0} \times K \times ( 1 + {cos}^{2} θ ) \times ( {π}^{2} {V}^{2} ) / ( {λ}^{4} \times {R}^{2} )$$

$$K = {( {n}^{2} - 1 )}^{2} / {( {n}^{2} + 2 )}^{2}$$

$${I}_{0} : The intensity of incident light$$

$$R : The distance to a scatter$$

$$λ : The wavelength of the incident light$$

$$V : The volume of the scatterer$$

$$n : The refractive index of the scatterer$$

$$θ : Angle of incidence$$

The symbol “x” is an operation symbol denoting multiplication. The symbol “/” is an operation symbol denoting division.

The foregoing equation reveals that when the emission peak wavelengths of the first subpixel X1 and second subpixel X2 are different, their scattering intensity levels become equal by making the size of the crystal grains C, which are scatterers, proportional to the two-thirds power of the emission peak wavelengths. That is, when average sizes d₁ and d₂ of the crystal grains C are proportional to the two-thirds power of emission peak wavelength L₁ and L₂, the light extraction efficiency is substantially constant regardless of the color of light from the light-emitting elements 10. This proportionality tolerates a 20%, 10%, or 5% difference. When the proportionality tolerates a 10% difference for instance, 0.9×d₁³/L₁²≤d₂³/L₂²≤1.1×d₁³/L₁² is satisfied.

When each of the first subpixel X1 and second subpixel X2 includes a plurality of light-reflective portions 3, in one or more of the light-reflective portions 3, the average size of the crystal grains C may be substantially equal between the first subpixel X1 and the second subpixel X2. For instance, when the emission peak wavelength of the second subpixel X2 is larger than the emission peak wavelength of the first subpixel X1, the average size of the crystal grains C1 in the first electrode E1 of the first subpixel X1 may be substantially equal to the average size of the crystal grains C1 in the first electrode E1 of the second subpixel X2, as illustrated in FIG. 18, and the average size of the crystal grains C2 in the hole injection layer HJ (functional layer) of the second subpixel X2 may be larger than the average size of the crystal grains C2 in the hole injection layer HJ (functional layer) of the first subpixel X1, as illustrated in FIG. 18.

When the emission peak wavelength of the second subpixel X2 is larger than the emission peak wavelength of the first subpixel X1, the average size of the crystal grains C2 in the hole injection layer HJ (functional layer) of the first subpixel X1 may be substantially equal to the average size of the crystal grains C2 in the hole injection layer HJ (functional layer) of the second subpixel X2, as illustrated in FIG. 19, and the average size of the crystal grains C1 in the first electrode E1 of the second subpixel X2 may be larger than the average size of the crystal grains C1 in the first electrode E1 of the first subpixel X1, as illustrated in FIG. 19. Layers that include crystal grains whose average size is substantially equal between the first subpixel X1 and the second subpixel X2 can be formed in the same process step, so that the efficiency of producing the display device 50 can be enhanced.

### Fifth Embodiment

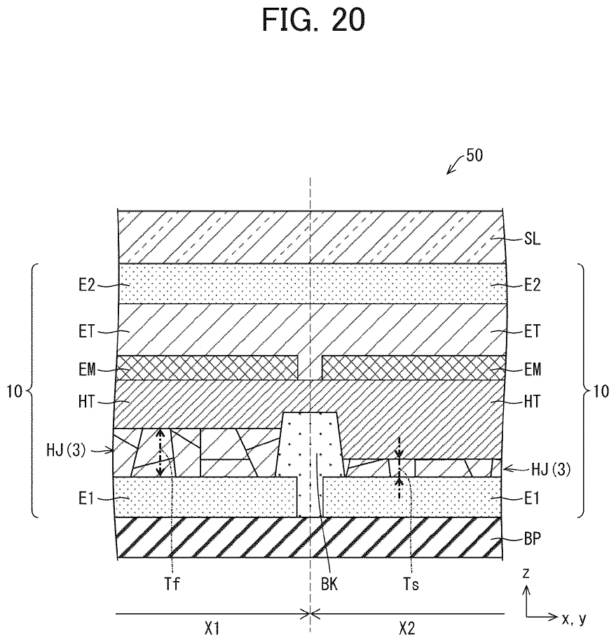

FIG. 20 is a cross-sectional view of an example of the configuration of a display device according to a fifth embodiment. In the fifth embodiment, the thickness of the light-reflective portion 3 is different between the first subpixel X1 and the second subpixel X2; that is, a thickness Tf in the first subpixel X1, and a thickness Ts in the second subpixel X2 (Tf>Ts). Also in the fifth embodiment, the average size of the crystal grains C in the light-reflective portion 3 is equal between the first subpixel X1 and the second subpixel X2. The emission peak wavelength L₁ of the first subpixel X1 is larger than the emission peak wavelength L₂ of the second subpixel X2.

In the configuration according to the fifth embodiment, when the thicknesses Tf and Ts of the light-reflective portion 3 are proportional to the two-thirds power of the emission peak wavelengths L₁ and L₂ of the emission layer EM in the first subpixel X1 and second subpixel X2, the light extraction efficiency is substantially constant regardless of the color of light from the light-emitting elements 10. This proportionality tolerates a 20%, 10%, or 5% difference. When the proportionality tolerates a 10% difference for instance, 0.9×Tf³/L₁²≤Ts³/L₂²≤1.1×Tf³/L₁² is satisfied.

When the emission peak wavelength is different between the first subpixel X1 and the second subpixel X2, optimizing both of the thickness of the light-reflective portion 3 and the average size of the crystal grains C can make the light extraction efficiency substantially constant regardless of the light emitted from the light-emitting elements 10.

The foregoing disclosures are illustrative and descriptive rather than restrictive. It should be noted that based on these illustrations and descriptions, various modifications are obvious for one of ordinary skill in the art, and that these modifications are also encompassed in the embodiments.

1. A light-emitting element comprising:
a first electrode;
a second electrode;
an emission layer positioned between the first electrode and the second electrode; and
a functional layer positioned between the first electrode and the emission layer,
wherein at least one of the first electrode and the functional layer is a light-reflective portion having a grain boundary, and whose surface adjacent to the emission layer has an average roughness of 3 to 20 nm.

2. The light-emitting element according to claim 1, wherein
the light-reflective portion includes a plurality of crystal grains forming the grain boundary, and
an average size of the plurality of crystal grains is equal to or less than one-tenth of an emission peak wavelength of the emission layer.

3. The light-emitting element according to claim 1, wherein
the light-reflective portion has a plurality of pits on the surface, and
an average depth of the plurality of pits ranges from 3 to 50 nm.

4. The light-emitting element according to claim 1, wherein
the light-reflective portion includes a plurality of crystal grains forming the grain boundary and has a plurality of pits on the surface, and
an average pit-to-pit distance between the plurality of pits is equal to or greater than an average size of the plurality of crystal grains.

5. The light-emitting element according to claim 1, wherein
the light-reflective portion has a plurality of pits on the surface, and
an average pit-to-pit distance between the plurality of pits is equal to or less than either the average roughness or an average depth of the plurality of pits, whichever is larger.

6. The light-emitting element according to claim 1, wherein
the light-reflective portion has a plurality of pits on the surface, and
an average pit-to-pit distance between the plurality of pits is equal to or less than a geometric mean of the average roughness and an average depth of the plurality of pits.

7. The light-emitting element according to claim 1, wherein
each of the first electrode and the functional layer is the light-reflective portion including a plurality of crystal grains forming the grain boundary, and
an average size of a plurality of crystal grains across the first electrode and the functional layer is equal to or less than one-tenth of an emission peak wavelength of the emission layer.

8. The light-emitting element according to claim 1, wherein
each of the first electrode and the functional layer is the light-reflective portion having a plurality of pits on the surface, and
an average depth of a plurality of pits ranges from 3 to 50 nm in each of the first electrode and the functional layer.

9. The light-emitting element according to claim 1, wherein
each of the first electrode and the functional layer is the light-reflective portion having a plurality of pits on the surface, and
an average pit-to-pit distance between a plurality of pits ranges from 3 to 50 nm in each of the first electrode and the functional layer.

10. The light-emitting element according to claim 1, wherein
each of the first electrode and the functional layer is the light-reflective portion having a plurality of pits on the surface, and including a plurality of crystal grains forming the grain boundary, and
in each of the first electrode and the functional layer, an average pit-to-pit distance between a plurality of pits is equal to or greater than an average size of a plurality of crystal grains.

11. (canceled)

12. The light-emitting element according to claim 1, comprising a plurality of functional layers positioned between the first electrode and the emission layer,
wherein each of the plurality of functional layers is a light-reflective portion having a grain boundary, and whose surface adjacent to the emission layer has an average roughness of 3 to 20 nm.

13. (canceled)

14. (canceled)

15. A display device comprising:
a first subpixel; and
a second subpixel configured to emit a color of light different from a color of light emitted from the first subpixel,
wherein each of the first subpixel and the second subpixel includes the light-emitting element according to claim 1.

16. The display device according to claim 15, wherein
in the first subpixel,
an average size of a plurality of crystal grains forming the grain boundary of the light-reflective portion is denoted as d₁, and
an emission peak wavelength of the emission layer is denoted as L₁,
in the second subpixel,
an average size of a plurality of crystal grains forming the grain boundary of the light-reflective portion is denoted as d₂, and
an emission peak wavelength of the emission layer is denoted as L₂, and
L₂>L₁ and d₂>d₁ are satisfied.

17. The display device according to claim 15, wherein
in the first subpixel,
an average size of a plurality of crystal grains forming the grain boundary of the light-reflective portion is denoted as d₁, and
an emission peak wavelength of the emission layer is denoted as L₁,
in the second subpixel,
an average size of a plurality of crystal grains forming the grain boundary of the light-reflective portion is denoted as d₂, and
an emission peak wavelength of the emission layer is denoted as L₂, and
0.9×d₁³/L₁²≤d₂³/L₂²≤1.1×d₁³/L₁² is satisfied.

18. The display device according to claim 15, wherein
in the first subpixel,
each of the first electrode and the functional layer is the light-reflective portion including a plurality of crystal grains forming the grain boundary,
an average size of a plurality of crystal grains across the first electrode and the functional layer is denoted as d₁, and
an emission peak wavelength of the emission layer is denoted as L₁,
in the second subpixel,
each of the first electrode and the functional layer is the light-reflective portion including a plurality of crystal grains forming the grain boundary,
an average size of a plurality of crystal grains across the first electrode and the functional layer is denoted as d₂, and
an emission peak wavelength of the emission layer is denoted as L₂, and
0.9×d₁³/L₁²≤d₂³/L₂²≤1.1×d₁³/L₁² is satisfied.

19. The display device according to claim 18, wherein an average size of a plurality of crystal grains in the first electrode of the first subpixel is equal to an average size of a plurality of crystal grains in the first electrode of the second subpixel.

20. The display device according to claim 18, wherein an average size of a plurality of crystal grains in the functional layer of the first subpixel is equal to an average size of a plurality of crystal grains in the functional layer of the second subpixel.

21. The display device according to claim 16, wherein the average size is an average particle diameter of a plurality of crystal grains.

22. (canceled)

23. The display device according to claim 15, wherein
in the first subpixel,
a thickness of the light-reflective portion is denoted as Tf, and
an emission peak wavelength of the emission layer is denoted as L₁,
in the second subpixel,
a thickness of the light-reflective portion is denoted as Ts, and
an emission peak wavelength of the emission layer is denoted as L₂, and
L₁>L₂ and Tf>Ts are satisfied.

24. The display device according to claim 15, wherein
in the first subpixel,
a thickness of the light-reflective portion is denoted as Tf, and
an emission peak wavelength of the emission layer is denoted as L₁,
in the second subpixel,
a thickness of the light-reflective portion is denoted as Ts, and
an emission peak wavelength of the emission layer is denoted as L₂, and
0.9×Tf³/L₁²≤Ts³/L₂²≤1.1×Tf³/L₁² is satisfied.

25. (canceled)

26. (canceled)
